(19) United States
(12) Patent Application Publication
(10) Pub. No.: US 2025/0174606 A1
(43) Pub. Date: May 29, 2025

(54) LIGHT-EMITTING DEVICE

(71) Applicant: Nichia Corporation, Anan-shi (JP)

(72) Inventors: Yoshiyuki KAGEYAMA, Tokushima-shi (JP); Hiroki NAKAI, Anan-shi (JP); Yuji SAKAKIHARA, Tokushima-shi (JP); Kensuke YAMAOKA, Tokushima-shi (JP); Kenta NISHII, Tokushima-shi (JP)

(21) Appl. No.: 18/934,312

(22) Filed: Nov. 1, 2024

(30) Foreign Application Priority Data
Nov. 24, 2023 (JP) 2023-199211

(51) Int. Cl. H01L 25/075; F21S 41/143; F21S 41/153; H01L 23/00

(52) U.S. Cl. CPC H01L 25/0753; F21S 41/143; F21S 41/153; H01L 24/32; H01L 24/29; H01L 2224/29139; H01L 2224/32245

(57) ABSTRACT

A light-emitting device includes a first substrate, a second substrate disposed above the first substrate, a plurality of light-emitting elements disposed on the second substrate, and a bonding member bonding a lower surface of the second substrate to the upper surface of the first substrate. The second substrate has a shape elongated in a first direction when viewed from above the second substrate, and has a thermal expansion coefficient different from that of the first substrate. The bonding member includes a first portion having a length in the first direction equal to or less than a length in a second direction orthogonal to the first direction, and second portions disposed on opposite sides of the first portion in the first direction, respectively. Each of the second portions has a Young's modulus and a thermal conductivity lower than those of the first portion.

### CROSS-REFERENCE TO RELATED APPLICATION

This application claims priority to Japanese Patent Application No. 2023-199211 filed on Nov. 24, 2023, the disclosure of which is hereby incorporated by reference in its entirety.

### BACKGROUND

### Technical Field

The present disclosure relates to a light-emitting device.

### Background Art

A light-emitting device has been studied in which a circuit board is disposed on a mounting substrate and a large number of light-emitting elements are disposed on the circuit board. Because a large amount of heat is generated when the large number of light-emitting elements emit light with high luminance, it is desirable that the light-emitting device has a property of high heat dissipation. On the other hand, because the mounting substrate and the circuit board generally have thermal expansion coefficients different from each other, warping may occur in the light-emitting device due to heat treatment during manufacture of the light-emitting device. When the warping occurs, optical accuracy of the light-emitting device may decrease. For example, see Japanese Patent Application Publication No. 2021-027116.

### SUMMARY

One object of certain embodiments of the present disclosure is to provide a light-emitting device in which both high heat dissipation and reduction of warping can be achieved.

A light-emitting device according to one or more embodiments includes a first substrate; a second substrate disposed above the first substrate, having a shape elongated in a first direction when viewed from above the second substrate, and having a thermal expansion coefficient different from a thermal expansion coefficient of the first substrate; a plurality of light-emitting elements disposed on the second substrate; and a bonding member bonding a lower surface of the second substrate to the upper surface of the first substrate. The bonding member includes a first portion having a length in the first direction equal to or less than a length in a second direction orthogonal to the first direction along the upper surface of the first substrate, and second portions disposed on opposite sides of the first portion in the first direction, respectively, each of the second portions having a Young's modulus lower than a Young's modulus of the first portion and a thermal conductivity lower than a thermal conductivity of the first portion.

According to certain embodiments of the present disclosure, a light-emitting device can be obtained in which both high heat dissipation and reduction of warping can be achieved.

### BRIEF DESCRIPTION OF DRAWINGS

FIG. 1 schematically illustrates a top view of a light-emitting device according to a first embodiment.

FIG. 2 schematically illustrates an enlarged top view of a region II of FIG. 1.

FIG. 3 schematically illustrates a cross-sectional view of the light-emitting device taken along line III-III illustrated in FIG. 1.

FIG. 4 schematically illustrates a top view of a bonding member of the light-emitting device according to the first embodiment.

FIG. 5 schematically illustrates a top view of a first substrate to illustrate a step of disposing a silver sintering paste and a silver paste on the first substrate in the first embodiment.

FIG. 6 schematically illustrates a cross-sectional view of a light-emitting device according to Comparative Example to illustrate the manner of warping occurred therein.

FIG. 7 schematically illustrates a cross-sectional view of the light-emitting device according to the first embodiment to illustrate the manner of warping occurred therein.

FIG. 8 schematically illustrates a top view of a bonding member of a light-emitting device according to a second embodiment.

FIG. 9 schematically illustrates a top view of a first substrate to illustrate a step of disposing the silver sintering paste and the silver paste on the first substrate in the second embodiment.

FIG. 10 schematically illustrates a cross-sectional view of a light-emitting device according to a third embodiment.

FIG. 11 schematically illustrates a top view of a bonding member of the light-emitting device according to the third embodiment.

FIG. 12 schematically illustrates a top view of the first substrate to illustrate a step of disposing the silver sintering paste and the silver paste on the first substrate in the third embodiment.

FIG. 13 schematically illustrates a top view of a bonding member of a light-emitting device according to a first modified example of the third embodiment.

FIG. 14 schematically illustrates a top view of a bonding member of a light-emitting device according to a second modified example of the third embodiment.

FIG. 15 schematically illustrates a top view of a bonding member of a light-emitting device according to a third modified example of the third embodiment.

FIG. 16 schematically illustrates a cross-sectional view of a light-emitting device according to a fourth embodiment.

FIG. 17 schematically illustrates a top view of a bonding member of the light-emitting device according to the fourth embodiment.

FIG. 18 schematically illustrates a top view of the first substrate to illustrate a step of disposing the silver sintering paste and the silver paste on the first substrate in the fourth embodiment.

FIG. 19 schematically illustrates a cross-sectional view of a light-emitting device according to a modified example of the fourth embodiment.

FIG. 20 schematically illustrates a top view of the first substrate to illustrate a step of disposing the silver sintering paste and the silver paste on the first substrate in the modified example of the fourth embodiment.

FIG. 21 schematically illustrates a cross-sectional view of a light-emitting device according to a fifth embodiment.

FIG. 22 schematically illustrates a cross-sectional view of a light-emitting device according to a sixth embodiment.

FIG. 23A schematically illustrates a top view of a bonding member of the light-emitting device according to the sixth embodiment.

FIG. 23B schematically illustrates a bottom view of a second substrate of the light-emitting device according to the sixth embodiment.

FIG. 24 schematically illustrates a enlarged cross-sectional view of a part of a light-emitting device according to a seventh embodiment.

FIG. 25A schematically illustrates a top view of the first substrate to illustrate a disposition of the silver sintering paste and the silver paste of a sample according to Comparative Example 1 in a test example.

FIG. 25B schematically illustrates a top view of the first substrate to illustrate a disposition of the silver sintering paste and the silver paste of a sample according to Example 1 in a test example.

FIG. 25C schematically illustrates a top view of the first substrate to illustrate a disposition of the silver sintering paste and the silver paste of a sample according to Example 2 in a test example.

FIG. 25D schematically illustrates a top view of the first substrate to illustrate a disposition of the silver sintering paste and the silver paste of a sample according to Example 3 in a test example.

FIG. 26A schematically illustrates a top view of a bonding member of a sample according to Comparative Example 1 in a test example.

FIG. 26B schematically is a top view of a bonding member of a sample according to Example 1 in a test example.

FIG. 26C schematically is a top view of a bonding member of a sample according to Example 2 in a test example.

FIG. 26D schematically is a top view of a bonding member of a sample according to Example 3 in a test example.

FIG. 27 is a graph showing a warping amount of each sample of the test examples with a horizontal axis representing the samples and a vertical axis representing warping amounts.

### DESCRIPTION OF EMBODIMENTS

### First Embodiment

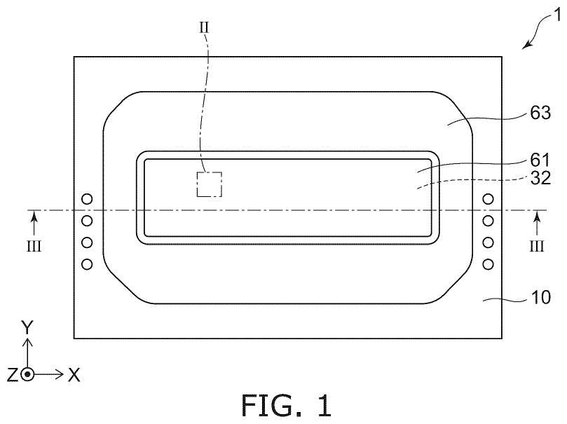

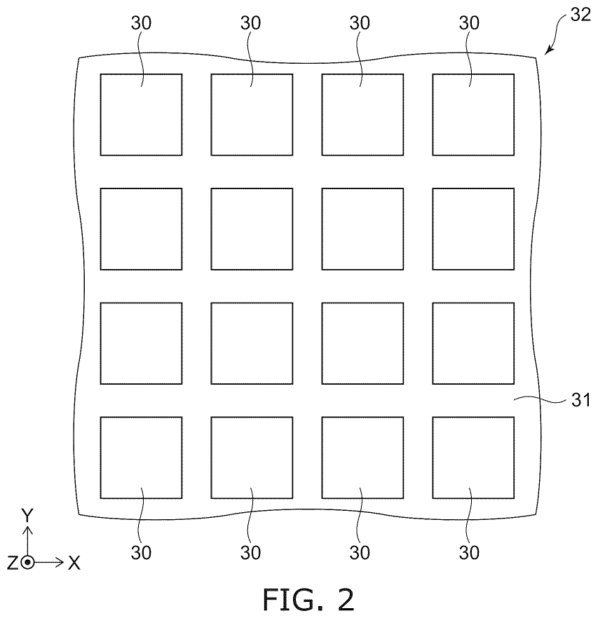

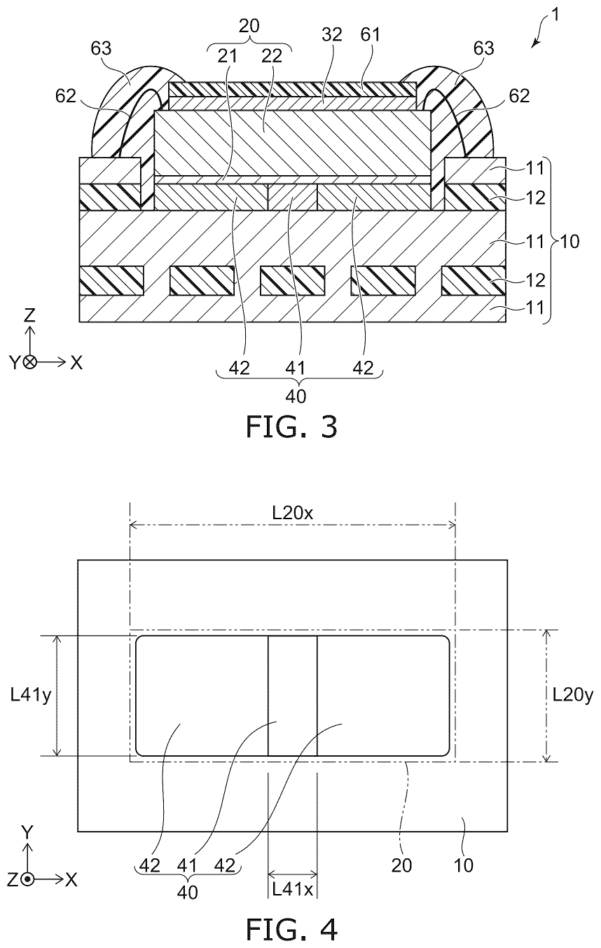

FIG. 1 schematically illustrates a top view of a light-emitting device according to a first embodiment. FIG. 2 schematically illustrates an enlarged top view of a region II of FIG. 1. FIG. 3 schematically illustrates a cross-sectional view of the light-emitting device taken along line III-III illustrated in FIG. 1. FIG. 4 schematically illustrates a top view of a bonding member of the light-emitting device according to the first embodiment.

All the drawings are illustrated schematically and may be exaggerated and simplified as appropriate. The aspect ratios and the positional relationships of components may or may not be exactly the same between the drawings. The same applies to other schematic views described below. It is noted, however, that the presented disclosure is intended to encompass at least the aspect ratios and the positional relationships of components illustrated in the drawings.

The configuration of a light-emitting device 1 according to the present embodiment will be schematically described. As illustrated in FIGS. 1 to 4, the light-emitting device 1 includes a first substrate 10, a second substrate 20, a plurality of light-emitting elements 30, and a bonding member 40. The second substrate 20 is disposed above the first substrate 10. A thermal expansion coefficient of the second substrate 20 is different from a thermal expansion coefficient of the first substrate 10. The plurality of light-emitting elements 30 are disposed on the second substrate 20. The bonding member 40 includes one first portion 41 and two second portions 42. A Young's modulus of the second portion 42 is lower than a Young's modulus of the first portion 41. A thermal conductivity of the first portion 41 is higher than a thermal conductivity of the second portion 42. In FIG. 4, the first substrate 10 is indicated by a solid line, and the second substrate 20 is indicated by a broken line.

Hereinafter, an XYZ orthogonal coordinate system is employed throughout the specification for convenience of description. A longitudinal direction of the second substrate 20 is referred to as a “first direction X”, a direction from/to the first substrate 10 to/from the second substrate 20 is referred to as a “third direction Z”, and a direction orthogonal to the first direction X and the third direction Z is referred to as a “second direction Y”. The third direction Z, when it is referred to for the direction from the first substrate 10 toward the second substrate 20, is referred to as an “upward direction,” and a direction opposite thereto is referred to as a “downward direction”. However, these expressions are used for convenience, and are independent of a gravity direction. Further, viewing in the third direction Z is referred to as a “top view”. The top view also includes a case in which when the light-emitting device 1 is viewed along the third direction Z, what is actually hidden by other components and cannot be seen is assumed to be seen.

As illustrated in FIG. 4, the second substrate 20 has a shape elongated in the first direction X. A length L20x of the second substrate 20 in the first direction X is longer than a length L20y of the second substrate 20 in the second direction Y. That is, L20x>L20y. The second portions 42 of the bonding member 40 are disposed on both sides of the first portion 41 in the first direction X. In the bonding member 40, a length L41x of the first portion 41 in the first direction X is equal to or less than a length L41y of the first portion 41 in the second direction Y. That is, L41x≤L41y. Further, as shown in FIG. 4, in a specific implementation, a length of each of the second portions 42 of the bonding member 40 in the first direction X is greater than the length L41x of the bonding member 40 in the first direction X. Here, the length of the first or second portions in the first direction X refers to a maximum length if the boundary between the first and second portions does not extend straight in the second direction Y. Furthermore, as shown in FIG. 4, in a specific implementation, the second portions 42 of the bonding member 40 are symmetrically disposed with respect to a center of the bonding member 40 in the first direction X.

A configuration of the light-emitting device 1 will be described in detail. The first substrate 10 contains, for example, a metal such as copper (Cu). The first substrate 10 is, for example, a copper core substrate. More specifically, as illustrated in FIG. 3, in the first substrate 10, a plurality of wiring layers 11 and a plurality of insulating layers 12 are layered. A conductive member made of copper is disposed as the wiring layer 11. Vias made of copper are disposed in the insulating layer 12. Thus, one of main components of the first substrate 10 is copper. The thickness of the first substrate 10, that is, the length in the third direction Z is, for example, 500 μm.

The second substrate 20 is, for example, a circuit board. The second substrate 20 contains, for example, a semiconductor such as silicon (Si). More specifically, the second substrate 20 is a semiconductor integrated circuit board, and is, for example, an application specific integrated circuit (ASIC) substrate. In the example herein, the main component of the second substrate 20 is silicon. Thus, the thermal expansion coefficient of the second substrate 20 is smaller than the thermal expansion coefficient of the first substrate 10. The shape of the second substrate 20 is a rectangular plate shape in which the first direction X is a longitudinal direction, the second direction Y is a lateral direction, and the third direction Z is a thickness direction. A metal layer 21 is provided on a lower surface side of the second substrate 20. The second substrate 20 includes a semiconductor portion 22 and a metal layer 21.

The light-emitting element 30 is, for example, a light-emitting diode (LED). As illustrated in FIGS. 2 and 3, in the light-emitting device 1, the plurality of light-emitting elements 30 are arranged in, for example, a matrix along an XY plane. A resin layer 31 is disposed between adjacent light-emitting elements 30. An LED array 32 includes the plurality of light-emitting elements 30 and the resin layer 31.

As illustrated in FIGS. 3 and 4, the bonding member 40 is disposed on substantially the entirety of the lower surface of the second substrate 20. Thus, the shape of the bonding member 40 is a rectangular plate shape in which the first direction X is a longitudinal direction, the second direction Y is a lateral direction, and the third direction Z is a thickness direction. The bonding member 40 is in contact with an upper surface of the first substrate 10 and a lower surface of the metal layer 21 of the second substrate 20.

The first portion 41 of the bonding member 40 contains sintered silver. In the sintered silver, a large number of silver particles are sintered together. Thus, the main component of the first portion 41 is silver (Ag). The second portion 42 of the bonding member 40 contains a solidified silver paste. In the solidified silver paste, silver particles are contained in a base material made of a resin, for example, silicone. Thus, the main components of the second portion 42 are the resin and silver.

The light-emitting device 1 may further include a phosphor layer 61, a plurality of wires 62, and a resin member 63. The phosphor layer 61 is disposed on the LED array 32. In the phosphor layer 61, a phosphor (not illustrated) is contained in a base material made of a resin. In FIG. 2, illustration of the phosphor layer 61 is omitted.

The wire 62 connects a terminal (not illustrated) of the first substrate 10 and a terminal (not illustrated) of the second substrate 20 to each other. The resin member 63 is disposed on a region of the first substrate 10 around a region in which the second substrate 20 is mounted and on an outer peripheral portion of the second substrate 20, and covers the wire 62. The shape of the resin member 63 is a frame shape in a top view.

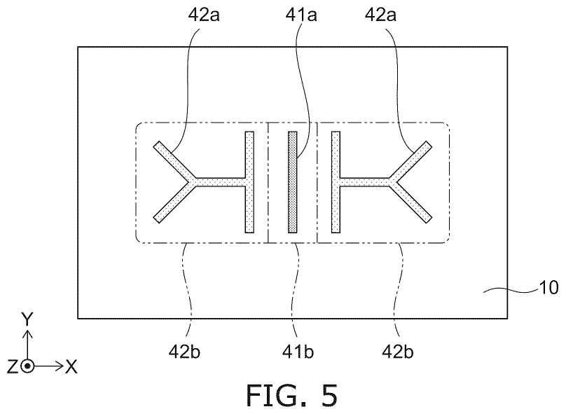

Next, a method for manufacturing the light-emitting device according to the present embodiment will be described. FIG. 5 schematically illustrates a top view of the first substrate 10 to illustrate a step of disposing the silver sintering paste and the silver paste on the first substrate 10 in the present embodiment. In FIG. 5, in the bonding member 40, a region in which the first portion 41 is to be formed is indicated as a “first region 41b” by a two-dot dash line, and a region in which the second portion 42 is to be formed is indicated as a “second region 42b” by a two-dot dash line.

First, the first substrate 10 is provided. In addition, a structure in which the plurality of light-emitting elements 30 are disposed on the second substrate 20 to form the LED array 32 is provided.

Subsequently, as illustrated in FIG. 5, the silver sintering paste 41a is disposed in the first region 41b on the first substrate 10. For example, the silver sintering paste 41a is disposed in a shape of one line extending in the second direction Y. The silver sintering paste 41a contains silver particles and a solvent as main materials.

The silver pastes 42a are disposed in the second regions 42b on the first substrate 10. For example, the silver paste 42a disposed in the second regions 42b includes a Y-shaped portion facing both sides in the first direction X and one line-shaped portion extending in the second direction Y. The silver paste 42a contains silver particles, a heat-curable resin, and a solvent as main materials. In a specific implementation, the silver sintering paste 41a is a paste to which a sintering process is performed, whereas the silver paste 42a is a paste to which no sintering process is performed, in which case the silver paste 42a may be referred to as silver non-sintering pastes.

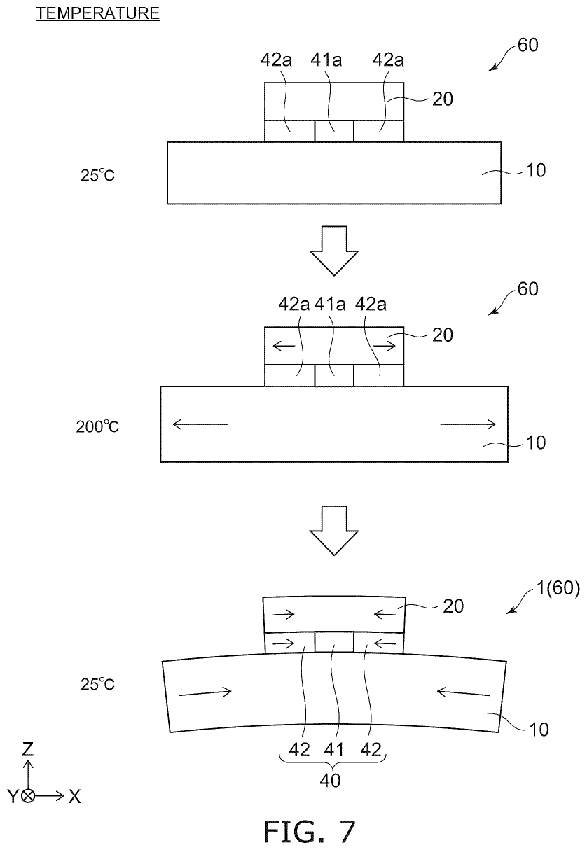

Subsequently, the structure including the second substrate 20 and the plurality of light-emitting elements 30 is brought into contact with the silver sintering paste 41a and the silver paste 42a and pressed against the first substrate 10. Thus, the silver sintering paste 41a is spread in the first region 41b, and the silver paste 42a is spread in the second region 42b. As a result, in a specific implementation, the silver sintering paste 41a and the silver pastes 42a on both sides thereof come in contact with each other, as shown in FIG. 7 described below.

Subsequently, the structure including the first substrate 10, the silver sintering paste 41a, the silver paste 42a, the second substrate 20, and the plurality of light-emitting elements 30 is heated to a temperature of, for example, 200° C. Thus, the solvent in the silver sintering paste 41a is volatilized, the silver particles are sintered with each other, and the first portion 41 is formed. At this time, the silver particles contained in the first portion 41 and the metal layer 21 react with each other and are bonded to each other. Further, the solvent in the silver paste 42a is volatilized and the resin is cured. As a result, the silver paste 42a is solidified to form the second portion 42.

In this manner, the bonding member 40 is formed, and the second substrate 20 is bonded to the first substrate 10. At this time, the shape of the first portion 41 is a substantially rectangular shape in a top view in which the length L41x in the first direction X is equal to or less than the length L41y in the second direction Y. The shape of each of the two second portions 42 is also the substantially rectangular shape in a top view.

Subsequently, as illustrated in FIG. 3, the wire 62 is bonded to the terminal of the first substrate 10 and the terminal of the second substrate 20. Subsequently, the phosphor layer 61 is disposed on the LED array 32. Subsequently, the resin member 63 is formed to cover the wire 62. In this manner, the light-emitting device 1 is manufactured.

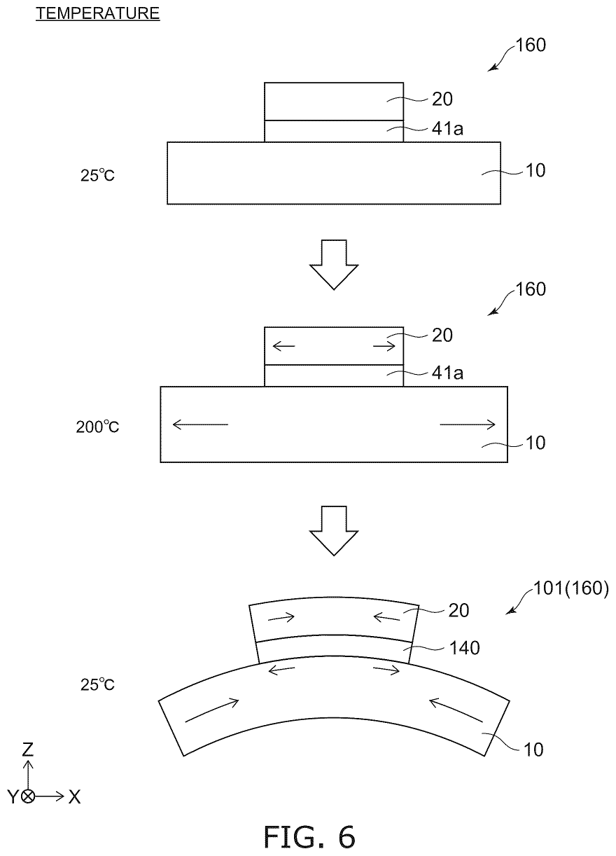

Effects and advantages of the present embodiment will be described below. FIG. 6 schematically illustrates a cross-sectional view of a light-emitting device according to Comparative Example to illustrate the manner of warping occurred therein during manufacturing. FIG. 7 schematically illustrates a cross-sectional view of the light-emitting device according to the present embodiment to illustrate warping occurred therein during manufacturing.

As illustrated in FIG. 6, in a light-emitting device 101 according to Comparative Example, a bonding member 140 is disposed between the first substrate 10 and the second substrate 20. The entirety of the bonding member 140 is made of sintered silver.

When the silver sintering paste 41a is disposed on the first substrate 10 and the second substrate 20 is disposed thereon at a room temperature, substantially no warping occurs in a structure 160 including the first substrate 10 and the second substrate 20.

Subsequently, when the first substrate 10 is heated to, for example, 200° C., in order to sinter the silver sintering paste 41a, the first substrate 10 expands more than the second substrate 20 because a thermal expansion coefficient of the first substrate 10 containing copper as a main component is larger than a thermal expansion coefficient of the second substrate 20 containing silicon as a main component. At this stage, sintering of the silver sintering paste 41a is not completed yet, and thus the Young's modulus is low. Thus, the expansion of the first substrate 10 is not significantly restricted by the second substrate 20, and a large warping does not occur in the structure 160. Thereafter, sintering of the silver sintering paste 41a is completed, and the bonding member 140 is formed.

Thereafter, when the structure 160 is cooled to a room temperature, the first substrate 10 tends to contract more than the second substrate 20, but at this stage, the second substrate 20 is firmly bonded to the first substrate 10 by the bonding member 140 made of the sintered silver, which has been sintered. Thus, the contraction of the first substrate 10 is restrained by the second substrate 20, and warping occurs in the structure 160 to be convex upward. This warpage also remains in the light-emitting device 101 after manufacturing. When the warping occurs in the light-emitting device 101, the optical accuracy decreases.

On the other hand, as illustrated in FIG. 7, in the light-emitting device 1 according to the present embodiment, the bonding member 40 includes the first portion 41 and the second portions 42 having a lower Young's modulus than the first portion 41. Thus, when the structure 60 including the first substrate 10 and the second substrate 20 is cooled to a room temperature after the bonding member 40 is formed, the contraction of the first substrate 10 is absorbed to some extent by the second portions 42 of the bonding member 40. As a result, warping of the light-emitting device 1 can be reduced.

Here, the Young's modulus can be determined by a calculation formula of E=σ/ε, where ε is strain (elongation amount), σ is stress (load), and E is a Young's modulus. More specifically, the Young's modulus of each of the first portion 41 and the second portion 42 can be determined by applying a load to each of the first portion 41 and the second portion 42 and measuring an elongation amount of each of the first portion 41 and the second portion 42 when the load is applied.

As illustrated in FIG. 4, with the length L20x in the first direction X longer than the length L20y in the second direction Y in the second substrate 20, warping is more likely to occur in the first direction X than in the second direction Y in the light-emitting device 1. In the present embodiment, the first portion 41 that restricts the deformation of the first substrate 10 has a shape in which the length L41x in the first direction X is equal to or less than the length L41y in the second direction Y, the restriction of the deformation in the first direction X is small. As a result, the warping of the light-emitting device 1 can be effectively reduced.

When the light-emitting element 30 emits light in the light-emitting device 1 after manufacturing, heat is generated. A part of the heat generated in the light-emitting element 30 is discharged to the outside via the second substrate 20, the bonding member 40, and the first substrate 10. In the bonding member 40, the thermal conductivity of the first portion 41 is higher than the thermal conductivity of the second portion 42, so that the light-emitting device 1 has a property of high heat dissipation. On the other hand, when the entirety of the bonding member 40 is made of silver paste, the occurrence of warping can be reduced, but the heat dissipation is lowered.

According to the present embodiment, with the first portion 41 having a relatively high thermal conductivity and Young's modulus and the second portion 42 having a relatively low thermal conductivity and Young's modulus that are arranged such that the second portions 42 are located on both sides of the first portion 41 in the first direction X and the length L41x of the first portion 41 in the first direction X is not larger than the length L41y of the first portion 41 in the second direction Y, the light-emitting device with high heat dissipation and reduced warpage can be achieved.

The light-emitting device 1 according to the present embodiment can be used as, for example, a light source for a headlamp of a vehicle. In this case, by individually controlling the plurality of light-emitting elements 30, an intensity distribution of the light emitted from the headlamp can be appropriately controlled, and an irradiation range can be selected. In this case, the luminances and the heat generation amounts of the light-emitting elements 30 may be different from each other depending on positions in the LED array 32.

For example, when high beam irradiation is performed by the headlamp, a high current is supplied to a group of light-emitting elements 30 disposed at the center of the LED array 32, and the group of light-emitting elements 30 exhibits high luminance. Because a large amount of heat is generated from the group of light-emitting elements 30, the first portion 41 is preferably located in a region directly below the group of light-emitting elements 30.

Although the example in which the first portion 41 is made of the silver sintering and the second portions 42 are made of the silver paste is described in the present embodiment, the present invention is not limited thereto. The first portion 41 may be made of, for example, a solder material such as AuSn solder or SAC solder. For example, the second portions 42 may be made of a resin-based adhesive containing filler of an Al paste, a graphene paste, or the like, or may be made of a resin-based adhesive of an epoxy resin, a silicone resin, an acrylic resin, or the like. The first portion 41 may be formed by plating with Cu, Au, Ag, or the like after forming the second portions 42. The first portion 41 may have higher thermal conductivity than the second portions 42, and the second portions 42 may have a lower Young's modulus than the first portion 41.

### Second Embodiment

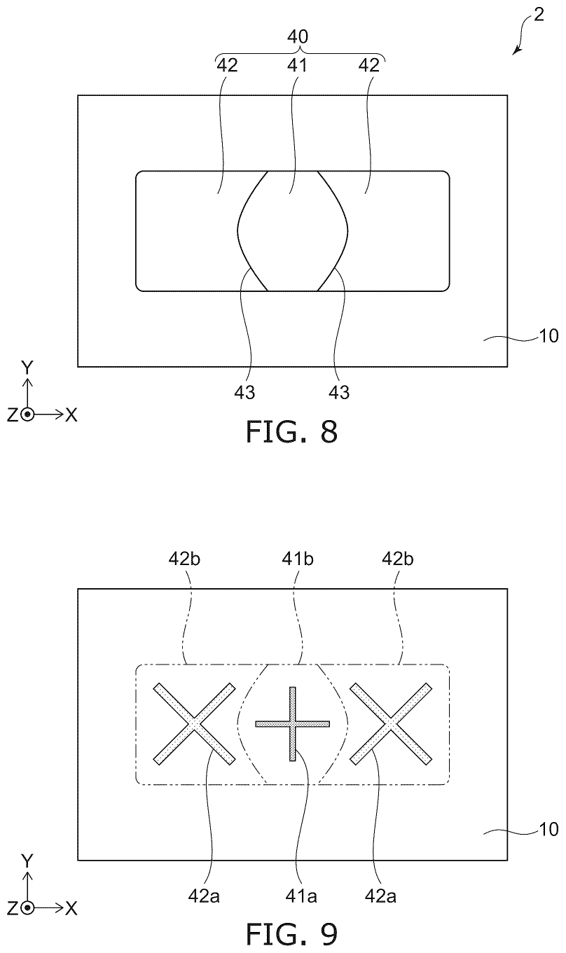

FIG. 8 schematically illustrates a top view of a bonding member of the light-emitting device according to a second embodiment. FIG. 9 schematically illustrates a top view of the first substrate to illustrate a step of disposing the silver sintering paste and the silver paste on the first substrate in the second embodiment.

As illustrated in FIG. 8, in a light-emitting device 2 according to the present embodiment, boundaries 43 between the first portion 41 and the second portions 42 of the bonding member 40 are curved lines that are convex on both sides of the first portion 41 in the first direction X in a top view. The first portion 41 and the second portions 42 are three-dimensional objects, so that the boundary 43 therebetween is a two-dimensional surface, for example, a curved surface. However, in the top view as illustrated in FIG. 8, the boundary 43 is represented as a line of intersection between an upper surface of the bonding member 40 and the boundary 43 which is a curved surface. That is, in the top view, the first portion 41 and the second portions 42 are two-dimensionally represented, so that the boundary 43 therebetween is represented by a one-dimensional line, for example, a curved line.

As illustrated in FIG. 9, the bonding member 40 in the present embodiment can be obtained by, for example, disposing the silver sintering paste 41a in a cross shape in the first region 41b and disposing the silver paste 42a in X shapes in the second regions 42b, in the step of disposing the silver sintering paste 41a and the silver paste 42a on the first substrate 10.

According to the present embodiment, by forming the boundaries 43 in curved shapes that are convex on both sides of the first portion 41 in the first direction X, formation of a corner portion having an acute angle in the first portion 41 after sintering is less likely to occur. Thus, concentration of a thermal stress can be reduced and a damage on the second substrate 20 and the light-emitting element 30 caused by the thermal stress can be reduced. Configurations other than those described above, a manufacturing method, and an effect in the present embodiment are the same as those in the first embodiment.

### Third Embodiment

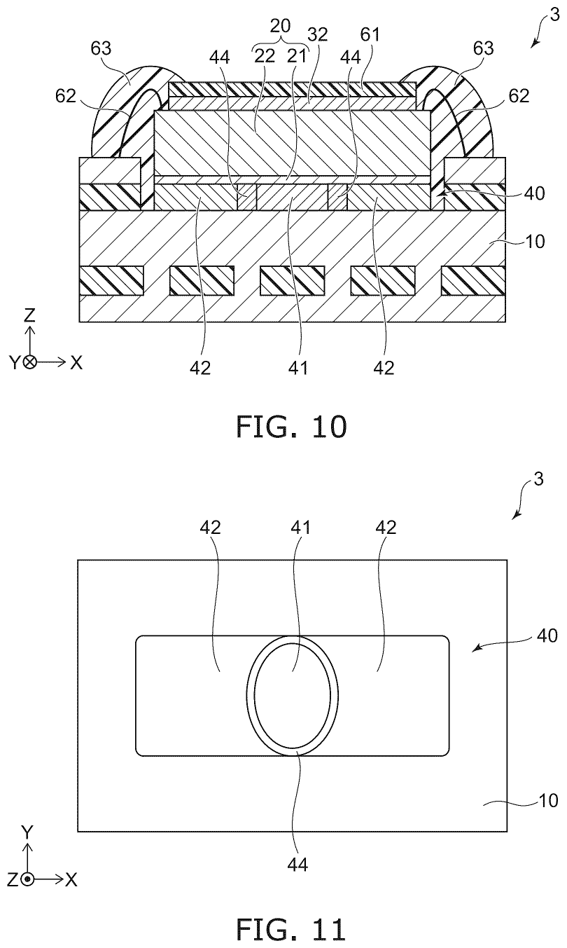

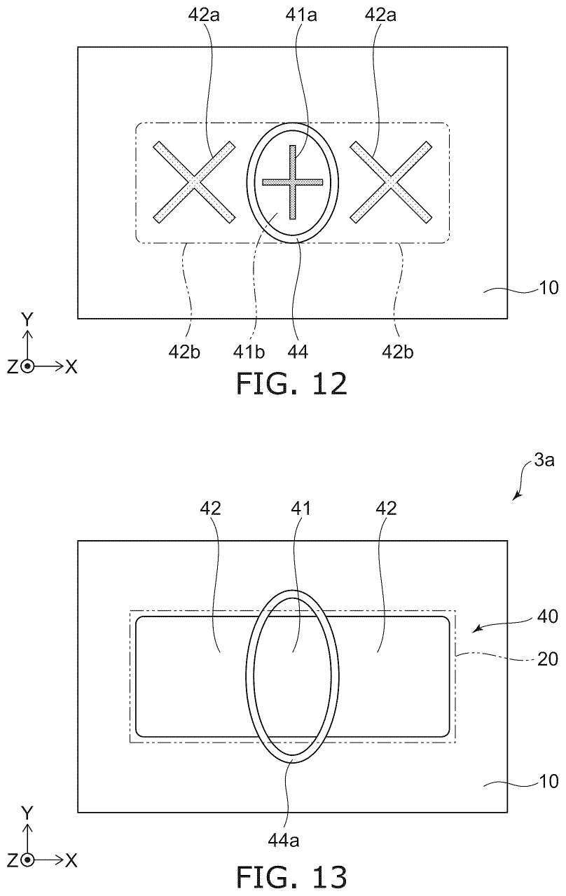

FIG. 10 schematically illustrates a cross-sectional view of a light-emitting device according to a third embodiment. FIG. 11 schematically illustrates a top view of a bonding member of the light-emitting device according to the present embodiment. FIG. 12 schematically illustrates a top view of the first substrate to illustrate a step of disposing the silver sintering paste and the silver paste on the first substrate in the third embodiment.

As illustrated in FIGS. 10 and 11, the light-emitting device 3 according to the present embodiment further includes a partition member 44 disposed between the first portion 41 and the second portion 42 of the bonding member 40. Any appropriate material can be used as a material of the partition member 44 and the material of the partition member 44 is not particularly limited as long as the material has heat resistance enough to undergo the manufacturing process of the light-emitting device 3. For example, the partition member 44 is made of a metal or a resin.

In the present embodiment, the shape of the partition member 44 is a frame shape, and is, for example, a substantially elliptical ring shape in which the length of the partition member 44 in the second direction Y is longer than the length thereof in the first direction X. The first portion 41 is disposed on the inside of the partition member 44, and the two second portions 42 are disposed on the outside of the partition member 44, that is, on both sides of the partition member 44 in the first direction X. In the present embodiment, the partition member 44 is located inward of the periphery of the second substrate 20 in a top view.

As illustrated in FIG. 12, in the method of manufacturing the light-emitting device 3, in the step of disposing the silver sintering paste 41a and the silver paste 42a, the partition member 44 is disposed on the first substrate 10, the silver sintering paste 41a is disposed in a cross shape inside the partition member 44, and the silver pastes 42a are disposed outside the partition member 44, that is, on both sides of the partition member 44 in the first direction X. However, the shapes of the silver sintering paste 41a and the silver paste 42a when they are disposed are not limited to the cross shape and the X shape, and may be any appropriate shape.

According to the present embodiment, by providing the partition member 44, the positions, shapes, and thicknesses of the first portion 41 and the second portions 42 can be further precisely configured. Configurations other than those described above, a manufacturing method, and an effect in the present embodiment are the same as those in the second embodiment.

### First Modified Example of Third Embodiment

FIG. 13 schematically illustrates a top view of a bonding member of a light-emitting device according to a first modified example of the third embodiment. As illustrated in FIG. 13, in a light-emitting device 3a according to the present modified example, a partition member 44a has a frame shape, and the partition member 44a partially protrudes outward of the second substrate 20 in a top view. More specifically, in a top view, the shape of the partition member 44a is a substantially elliptical shape in which the length of the partition member 44a in the second direction Y is longer than the length thereof in the first direction X, and both end portions of the partition member 44a in the second direction Y protrude outward of the second substrate 20. In addition, both end portions of a space having a substantially elliptical shape surrounded by the partition member 44a in the second direction Y also protrude outward of the second substrate 20 in a top view.

According to the present modified example, when the partition member 44a partially protrude outward of the second substrate 20 in a top view, voids and a solvent contained in the silver sintering paste 41a can be released to the outside of the bonding member 40 when the silver sintering paste 41a is sintered. Thus, the quality of the sintered silver after sintering is improved. Configurations other than those described above, a manufacturing method, and an effect in the present modified example are the same as those in the third embodiment.

### Second Modified Example of Third Embodiment

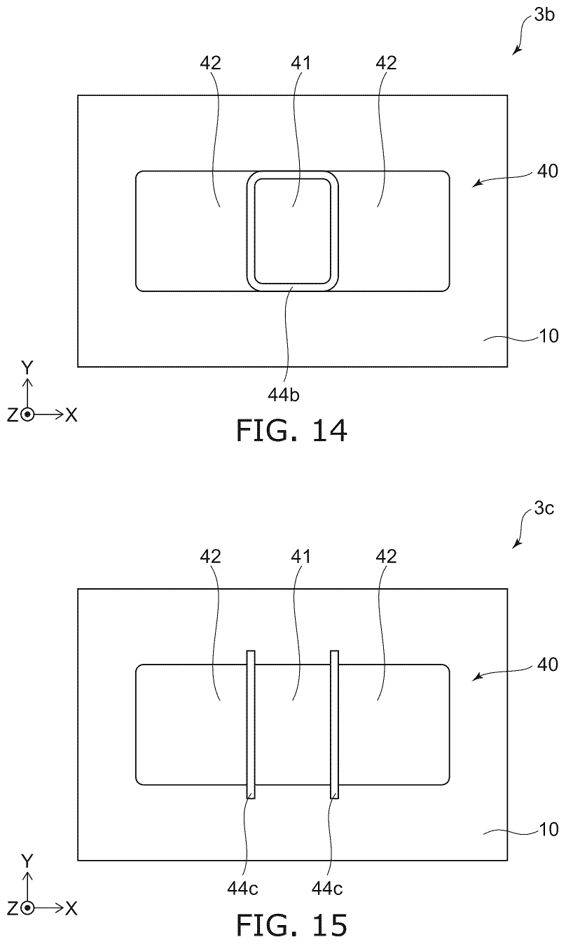

FIG. 14 schematically illustrates atop view of a bonding member of a light-emitting device according to a second modified example of the third embodiment. As illustrated in FIG. 14, in a light-emitting device 3b according to the present modified example, the shape of a partition member 44b is a frame shape and a substantially rectangular shape in a top view. The length of the partition member 44b in the second direction Y is longer than the length thereof in the first direction X. Configurations other than those described above, a manufacturing method, and an effect in the present modified example are the same as those in the third embodiment. As in the first modified example of the third embodiment, part of the partition member 44b may be provided so as to protrude outward of the second substrate 20.

### Third Modified Example of Third Embodiment

FIG. 15 schematically illustrates a top view of a bonding member of a light-emitting device according to a third modified example of the third embodiment. As illustrated in FIG. 15, in a light-emitting device 3c according to the present modified example, the shape of partition members 44c is not a frame shape but two bar shapes in which the second direction Y is a longitudinal direction in a top view. The two partition members 44c are disposed so as to be spaced apart from each other in the first direction X. The first portion 41 is disposed between the two partition members 44c, and the second portions 42 are disposed on both sides of the two partition members 44c in the first direction X. Configurations other than those described above, a manufacturing method, and an effect in the present modified example are the same as those in the third embodiment.

### Fourth Embodiment

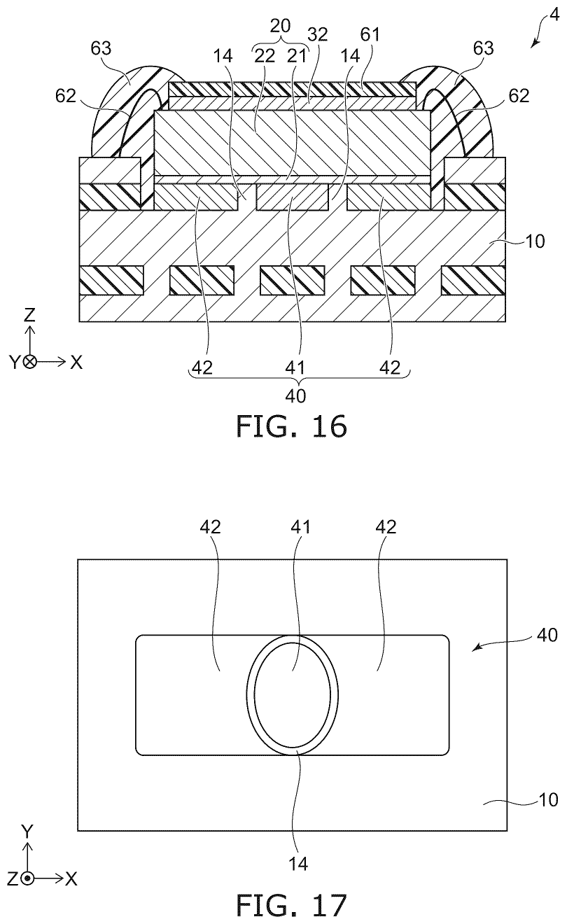

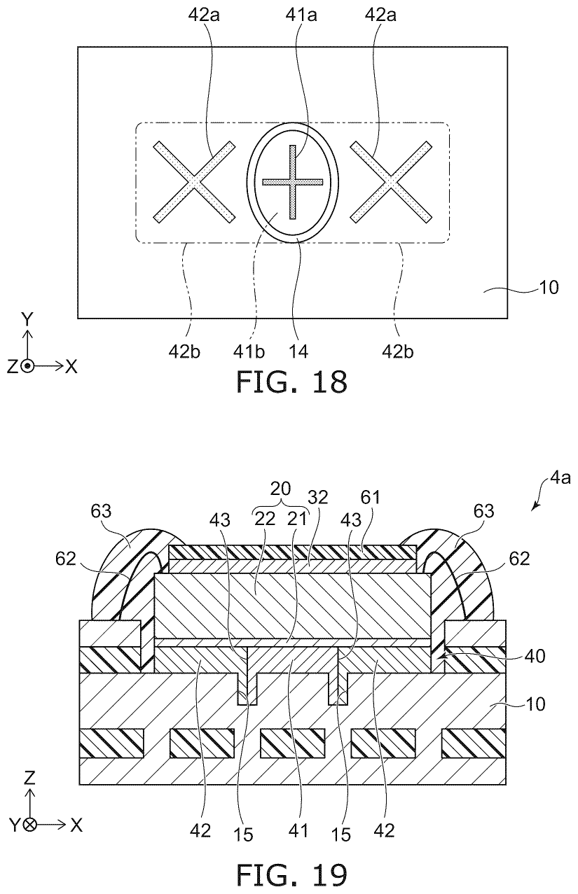

FIG. 16 schematically illustrates a cross-sectional view of a light-emitting device according to a fourth embodiment. FIG. 17 schematically illustrates a top view of a bonding member of the light-emitting device according to the fourth embodiment. FIG. 18 schematically illustrates a top view of the first substrate to illustrate a step of disposing the silver sintering paste and the silver paste on the first substrate in the fourth embodiment.

As illustrated in FIGS. 16 and 17, in the light-emitting device 4 according to the present embodiment, the first substrate 10 includes a protruded portion 14 on an upper surface side thereof. The protruded portion 14 is made of, for example, copper. The protruded portion 14 is located between the first portion 41 and the second portion 42 of the bonding member 40. In a specific implementation, the protruded portion 14 is integrally formed with an underlying wiring layer 11 directly beneath the protruded portion 14.

The shape of the protruded portion 14 is a frame shape, and is, for example, a substantially elliptical ring shape in a top view. The length of the protruded portion 14 in the second direction Y is equal to or larger than the length thereof in the first direction X. The first portion 41 is located inward of the protruded portion 14, and the two second portions 42 are located outward of the protruded portion 14, that is, on both sides of the protruded portion 14 in the first direction X. In the present embodiment, the protruded portion 14 is located inward of the periphery of the second substrate 20 in a top view.

As illustrated in FIG. 18, in the method of manufacturing the light-emitting device 4 according to the present embodiment, in the step of disposing the silver sintering paste 41a and the silver pastes 42a which are unsolidified, the silver sintering paste 41a is disposed in a cross shape inward of the protruded portion 14 of the first substrate 10, and the silver pastes 42a are disposed in an X shape outward of the protruded portion 14 and on both sides the protruded portion 14 in the first direction X. However, the shapes of the silver sintering paste 41a and the silver paste 42a when they are disposed are not limited to the cross shape and the X shape, and may be any shape. Configurations other than those described above, a manufacturing method, and an effect in the present embodiment are the same as those in the third embodiment.

### Modified Example of Fourth Embodiment

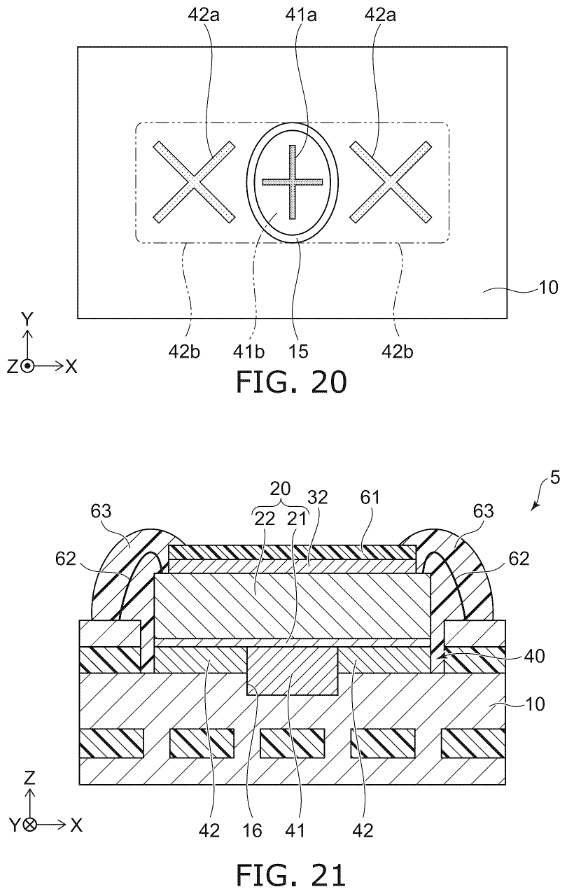

FIG. 19 schematically illustrates a cross-sectional view of a light-emitting device according to a modified example of the fourth embodiment. FIG. 20 schematically illustrates a top view of the first substrate to illustrate a step of disposing the silver sintering paste and the silver paste on the first substrate in the present modified example.

As illustrated in FIG. 19, in a light-emitting device 4a according to the present modified example, the first substrate 10 includes a groove 15 on the upper surface side thereof. A part of the first portion 41 and/or a part of at least one of the second portions 42, for example, all of these, of the bonding member 40 are disposed in the groove 15. Thus, the boundary 43 between the first portion 41 and the second portion 42 overlaps the groove 15 in a top view.

As illustrated in FIG. 20, in a method of manufacturing the light-emitting device 4a according to the present modified example, the silver sintering paste 41a before sintering is disposed in a region surrounded by the groove 15 in the first substrate 10, and the silver pastes 42a are disposed on both sides of the groove 15 in the first direction X. Thus, when the silver sintering paste 41a and the silver pastes 42a are pressed and spread by the second substrate 20, the silver sintering paste 41a and the silver pastes 42a fall into the groove 15, so that the silver sintering paste 41a and the silver pastes 42a are less likely to further spread. As a result, the position of the boundary 43 can overlap the groove 15 in a top view.

In this manner, the position of the boundary 43 is defined by the groove 15, and the positions and shapes of the first portion 41 and the second portions 42 can be configured with high accuracy. Configurations other than those described above, a manufacturing method, and an effect in the present modified example are the same as those in the fourth embodiment.

### Fifth Embodiment

FIG. 21 schematically illustrates a cross-sectional view of a light-emitting device according to a fifth embodiment. As illustrated in FIG. 21, in a light-emitting device 5 according to the present embodiment, the first substrate 10 defines a recess 16 at the upper surface side of the first substrate 10. The first portion 41 of the bonding member 40 is located in the recess 16 in a top view. On the other hand, the second portions 42 of the bonding member 40 are located on both sides of the recess 16 in the first direction X in a top view.

Thus, the thickness of the first portion 41, that is, the length in the third direction Z is larger than the thickness of the second portion 42. In one example, the thickness of the first substrate 10 is 500 μm and the depth of the recess 16 is 50 μm. The thickness of the first portion 41 is in a range from 60 μm to 80 μm, and the thickness of the second portion 42 is in a range from 10 μm to 30 μm.

In the present embodiment, by disposing the silver sintering paste 41a in the recess 16, the first portion 41 can be formed in the recess 16 and a region immediately above the recess 16. Thus, an outer edge of the first portion 41 can be defined by an outer edge of the recess 16, and shape accuracy of the first portion 41 is improved.

For the first portion 41 made of the sintered silver, the thinner the first portion 41, the higher the residual stress. Thus, the first portion 41 is preferably thick in consideration of the residual stress. On the other hand, for the second portions 42 made of the silver paste, the thinner the second portions 42, the higher the heat dissipation. Thus, the second portions 42 are preferably thin from the viewpoint of the heat dissipation. In the present embodiment, by forming the first portion 41 thicker than the second portions 42, the heat dissipation can be improved while reducing the residual stress. Configurations other than those described above, a manufacturing method, and an effect in the present embodiment are the same as those in the first embodiment.

### Sixth Embodiment

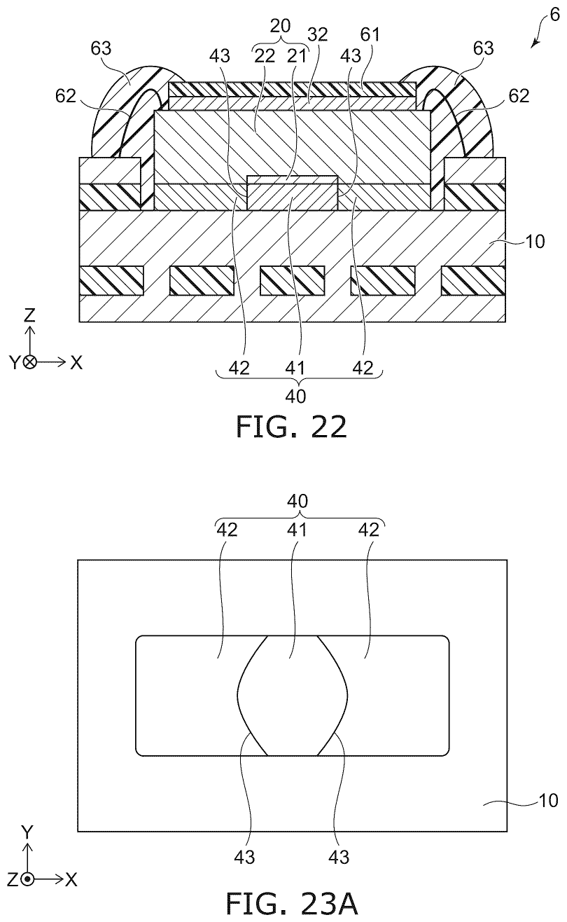

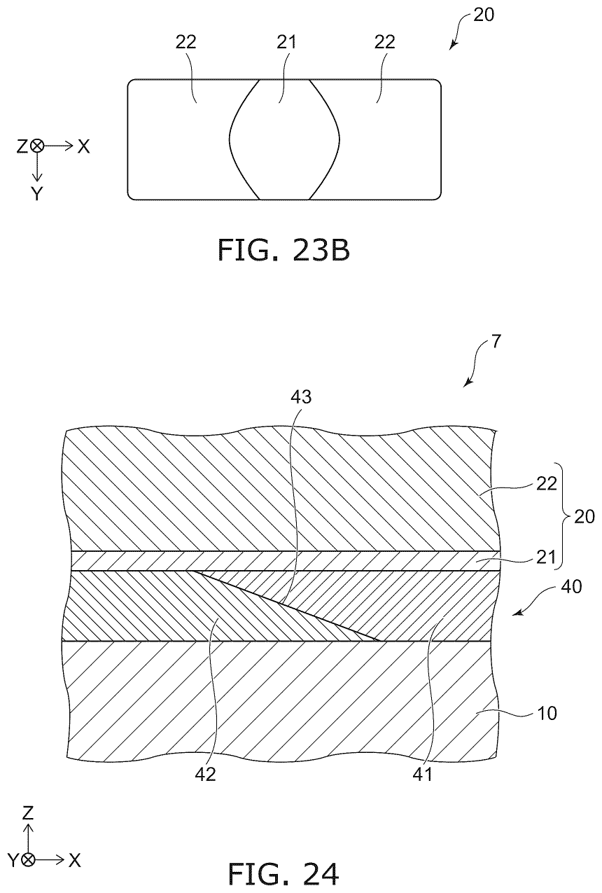

FIG. 22 schematically illustrates a cross-sectional view of a light-emitting device according to a sixth embodiment. FIG. 23A schematically illustrates a top view of a bonding member of the light-emitting device according to the sixth embodiment. FIG. 23B schematically illustrates a bottom view of a second substrate of the light-emitting device according to the sixth embodiment.

As illustrated in FIGS. 22, 23A and 23B, in a light-emitting device 6 according to the present embodiment, the metal layer 21 of the second substrate 20 is disposed selectively in a region facing the first portion 41 of the bonding member 40. Thus, the first portion 41 of the bonding member 40 is in contact with the metal layer 21 of the second substrate 20, and the second portions 42 of the bonding member 40 are in contact with the semiconductor portion 22 of the second substrate 20. In other words, a bonded surface of the metal layer 21 substantially coincides with a bonded surface of the first portion 41 that is bonded to the second substrate 20, and a bonded surface of the semiconductor portion 22 substantially coincides with a bonded surface of the second portions 42 that is bonded to the second substrate 20.

However, an outer edge of the metal layer 21 need not exactly coincide with the boundary 43 between the first portion 41 and the second portion 42 in a top view.

The sintered silver contained in the first portion 41 reacts with the metal layer 21 to be bonded to the second substrate 20. Thus, the first portion 41 is preferably in contact with the metal layer 21. On the other hand, in the silver paste contained in the second portions 42, bonding strength with silicon is higher than bonding strength with a metal. Thus, the second portions 42 are preferably in contact with the semiconductor portion 22. In the present embodiment, materials having good compatibility with each other are bonded to each other, so that the bonding strength between the first substrate 10 and the second substrate 20 is high. Configurations other than those described above, a manufacturing method, and an effect in the present embodiment are the same as those in the first embodiment.

### Seventh Embodiment

FIG. 24 schematically illustrates an enlarged cross-sectional view of a part of a light-emitting device according to a seventh embodiment. As illustrated in FIG. 24, in a light-emitting device 7 according to the present embodiment, an end portion of the first portion 41 of the bonding member 40 extends on an end portion of the second portion 42 thereof. Thus, a part of the first portion 41 and a part of the second portion 42 overlap each other in a top view. It is noted that the end portion of the second portion 42 may extend on the end portion of the first portion 41. In a specific implementation, as shown in FIG. 24, a boundary between the end portion of the first portion 41 of the bonding member 40 and the end portion of the second portion 42 thereof is tilted with respect to the first direction X. In the present embodiment, the boundary 43 between the first portion 41 and the second portion 42 is a region having a width in a top view. In this case, as described above, an intersection line between the upper surface of the bonding member 40 and the boundary 43 is represented as the boundary 43 in a top view. The boundaries 43 each defined in this manner may be curved lines that are convex on both sides of the first portion 41 in the first direction X in a top view.

In the present embodiment, near the boundary 43, part of silver contained in the sintered silver of the first portion 41 and part of silver contained in the silver paste of the second portion 42 are melted and bonded to each other. The first portion 41 and the second portion 42 are less likely to be separated from each other due to an effect of melting and bonding of silver in this manner and an anchor effect between the first portion 41 and the second portion 42. As a result, the bonding strength between the first substrate 10 and the second substrate 20 is improved. Configurations other than those described above, a manufacturing method, and an effect in the present embodiment are the same as those in the first embodiment.

### Test Examples

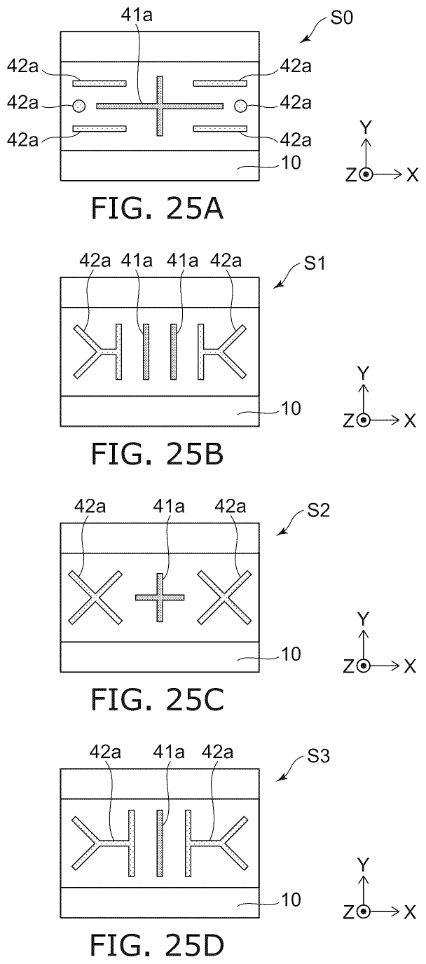

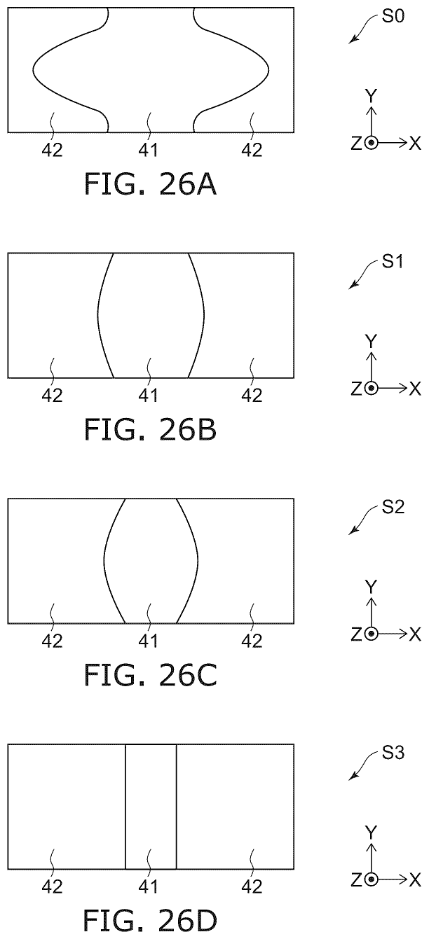

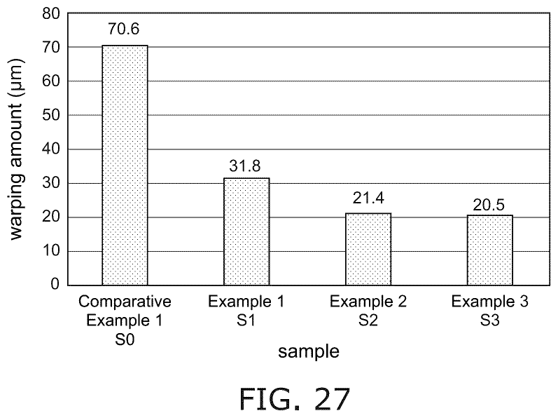

FIGS. 25A to 25D schematically illustrate top views of the silver sintering paste and the silver paste of corresponding samples, respectively, in the present test example. FIGS. 26A to 26D schematically illustrate top views of a bonding member of corresponding samples, respectively, in the present test examples. FIG. 27 is a graph showing a warping amount of each sample of the present test examples with a horizontal axis representing the samples and a vertical axis representing warping amounts.

In the present test examples, a plurality of samples were manufactured in which the second substrate 20 was bonded to the first substrate 10 via the bonding member 40. The arrangement of the first portion 41 and the second portion 42 in the bonding member 40 varied among the samples. After the bonding member 40 was formed by sintering the silver sintering paste 41a and solidifying the silver paste 42a, the warping amount of each sample at a temperature of 50° C. was measured.

As illustrated in FIGS. 25A and 26A, in a sample S0 according to Comparative Example 1, the length of the first portion 41 in the first direction X is longer than the length thereof in the second direction Y. Comparative Example 1 illustrated in FIGS. 25A and 26A is an example different from Comparative Example illustrated in FIG. 6.

As illustrated in FIGS. 25B and 26B, a sample S1 according to Example 1 corresponds to the light-emitting device according to the above-described first embodiment, and the length of the first portion 41 in the first direction X is shorter than the length thereof in the second direction Y.

As illustrated in FIGS. 25C and 26C, a sample S2 according to Example 2 corresponds to the light-emitting device according to the above-described second embodiment, the length of the first portion 41 in the first direction X is shorter than the length thereof in the second direction Y, and the boundaries 43 are curved lines that are convex on both sides of the first portion 41 in the first direction X.

As illustrated in FIGS. 25D and 26D, a sample S3 according to Example 3 corresponds to the light-emitting device according to the above-described first embodiment, but the length of the first portion 41 in the first direction X is shorter than that of the sample S1.

As shown in FIG. 27, the warping amount of the sample S1 according to Example 1 was half or less of the warping amount of the sample SO according to Comparative Example 1. The warping amounts of the sample S2 according to Example 2 and the sample S3 according to Example 3 were smaller than the warping amount of the sample S1 according to Example 1.

Each of the above-described embodiments and modified examples is an example embodying the present invention, and the present invention is not limited to these embodiments and modified examples. For example, in each of the above-described embodiments and modified examples, those in which some of the components or steps are added, omitted, or changed are also included in the present invention. The above-described embodiments and modified examples can be implemented in combination with each other.

A light-emitting device of the present disclosure can be utilized for a light source for a headlamp of a vehicle and the like.

What is claimed is:

1. A light-emitting device comprising:
a first substrate;
a second substrate disposed above the first substrate, having a shape elongated in a first direction when viewed from above the second substrate, and having a thermal expansion coefficient different from a thermal expansion coefficient of the first substrate;
a plurality of light-emitting elements disposed on the second substrate; and
a bonding member bonding a lower surface of the second substrate to the upper surface of the first substrate, wherein
the bonding member comprises:
a first portion having a length in the first direction equal to or less than a length in a second direction orthogonal to the first direction along the upper surface of the first substrate, and
second portions on opposite sides of the first portion in the first direction, respectively, each of the second portions having a Young's modulus lower than a Young's modulus of the first portion and a thermal conductivity lower than a thermal conductivity of the first portion.

2. The light-emitting device according to claim 1, wherein a boundary between the first portion and each of the second portions is a curved line that is convex toward the first portion in the first direction in a top view.

3. The light-emitting device according to claim 1, further comprising a partition member disposed between the first portion and at least one of the second portions.

4. The light-emitting device according to claim 3, wherein the partition member has a frame shape.

5. The light-emitting device according to claim 4, wherein the frame shape of the partition member is an elliptical ring shape.

6. The light-emitting device according to claim 4, wherein the frame shape of the partition member is a rectangular ring shape.

7. The light-emitting device according to claim 4, wherein
a part of the partition member protrudes outward of the second substrate in the second direction in a top view.

8. The light-emitting device according to claim 1, wherein the length of the first portion in the first direction is less than a length of each of the second portions in the first direction.

9. The light-emitting device according to claim 1, wherein the second portions are symmetrically disposed with respect to a center of the bonding member in the first direction.

10. The light-emitting device according to claim 1, wherein the first portion is in contact with each of the second portions.

11. The light-emitting device according to claim 1, wherein a part of the first portion and a part of at least one of the second portions overlap each other in a top view.

12. The light-emitting device according to claim 11, wherein at an overlapped region of the bonding member where the part of the first portion overlaps with the part of at least one of the second portions, a boundary of the first portion and the second portion is tilted with respect to the first direction in a cross-sectional view.

13. The light-emitting device according to claim 1, wherein
the first substrate comprises a protruded portion on the upper surface thereof, and
the protruded portion is located between the first portion and each of the second portions.

14. The light-emitting device according to claim 1, wherein
the first substrate comprises a groove on the upper surface thereof, and
a boundary between the first portion and at least one of the second portions overlaps the groove in a top view.

15. The light-emitting device according to claim 1, wherein
the first substrate comprises a recess at an upper surface thereof, and
the first portion is located in the recess in a top view.

16. The light-emitting device according to claim 1, wherein
the second substrate comprises
a semiconductor portion, and
a metal layer disposed on a lower surface side of the semiconductor portion,
the first portion is in contact with the metal layer, and
the second portions are in contact with the semiconductor portion.

17. The light-emitting device according to claim 16, wherein a bonded surface of the metal layer substantially coincides with a bonded surface of the first portion that is bonded to the second substrate, and a bonded surface of the semiconductor portion substantially coincides with a bonded surface of the second portions that is bonded to the second substrate.

18. The light-emitting device according to claim 1, wherein
the first substrate contains a metal, and
the second substrate contains a semiconductor.

19. The light-emitting device according to claim 1, wherein
the first portion contains sintered silver, and
the second portions contain a solidified silver paste.

20. The light-emitting device according to claim 1, wherein the light-emitting device is a light source for a vehicle headlamp.
